(19) United States
(12) Patent Application Publication
(10) Pub. No.: US 2026/0243812 A1
(43) Pub. Date: Aug. 20, 2026

(54) REVERBERATION CHAMBER AND MEASUREMENT SYSTEM COMPRISING THE SAME

(71) Applicant: ANTENNEX HOLDING B.V., Eindhoven (NL)

(72) Inventors: Anouk HUBRECHSEN, Eindhoven (NL); Antonius Johannes VAN DEN BIGGELAAR, Eindhoven (NL); Roel Xander Franciscus BUDÉ, Eindhoven (NL); Timotheüs STEK, Eindhoven (NL)

(21) Appl. No.: 19/489,534

(22) PCT Filed: Jun. 5, 2024
(86) PCT No.: PCT/NL2024/050286

§ 371 Date: Dec. 2, 2025

(30) Foreign Application Priority Data
Jun. 9, 2023 (NL) 2035158

(51) Int. Cl. G01R 29/10

(52) U.S. Cl. CPC G01R 29/105

(57) ABSTRACT

The present disclosure relates to a reverberation chamber for testing an antenna, such as a transmitting antenna or a receiving antenna, and to a measurement system comprising the same. A reverberation chamber for testing an antenna, comprising a plurality of electromagnetically reflective walls together defining a chamber volume, the chamber volume being configured to receive, at a first position, a transmitting antenna. The reverberation chamber further comprises an electromagnetically reflective structure arranged at or integrally formed with a first wall among the plurality of walls. The structure is arranged along a shortest path from the first position to a plane in which said first wall extends and is configured to reflect at lease part of electromagnetic waves, originating from the first position and incident on the structure, away from the first position.

### FIELD

The present disclosure relates to a reverberation chamber for testing an antenna, such as a transmitting antenna or a receiving antenna. The present disclosure further relates to a measurement system comprising such a reverberation chamber.

### BACKGROUND

A reverberation chamber is a type of electromagnetic (EM) testing chamber and can be used to measure the performance of electronic devices and equipment, such as antennas.

Reverberation chambers for testing an antenna are known in the art. Generally, such a conventional reverberation chamber comprises a plurality of electromagnetically reflective walls together defining a chamber volume. A transmitting antenna and receiving antenna can be provided in the chamber volume for performing a measurement for either or both of the transmitting antenna and receiving antenna.

A typical reverberation chamber includes one or more mode stirring units arranged in the chamber volume and configured to be adjustable between a plurality of mode stirring states, corresponding to different positions and/or orientations of said one or more stirring units or otherwise configurable reflective states thereof, to thereby change a reflection behavior of electromagnetic waves within the chamber volume.

During operation, the transmitting antenna emits electromagnetic waves in the chamber volume and the receiving antenna receives said electromagnetic waves after one or more reflections via the plurality of walls and/or the mode stirring units. It is noted here that, since the plurality of walls are typically static and the mode stirring units are adjustable between a plurality of mode stirring states, energy reflected only by the plurality of walls may not change in dependence of the mode stirring states, and thus may hereinafter be referred to as unstirred energy. On the other hand, energy reflected at least once by the mode stirring units may be different among different mode stirring states, and may hereinafter be referred to as stirred energy.

By averaging over several mode stirring states, a substantially uniform and isotropic field distribution is ideally effectively created within the chamber volume. Statistical properties of the generated fields can then be used to derive one or more characteristics of antenna-system parameters. However, a relatively large unstirred energy component may influence the accuracy of the measurement.

To prevent this, highly directional antennas are typically placed at an oblique angle with respect to the plurality of walls. While this approach may be feasible to some extent for passive antennas having a static radiation pattern, recent developments, such as 5G applications and beyond, have led to a more widespread use of antenna arrays or phased arrays, of which a direction of maximum radiation can be controlled. Especially for antenna systems with such a configurable radiation pattern, it may be challenging, if not impossible, to find a proper antenna placement and orientation of the antenna without compromising on measurement accuracy. Nevertheless, even for antennas with static radiation patterns, a large unstirred energy component may be a concern.

### SUMMARY

It is an object of the present disclosure to provide a reverberation chamber and measurement system in which the abovementioned problem(s) do not occur or at least to a lesser extent.

A summary of aspects of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects and/or a combination of aspects that may not be set forth.

According to an aspect of the present disclosure, a reverberation chamber for testing an antenna is provided, comprising a plurality of electromagnetically reflective walls together defining a chamber volume, the chamber volume being configured to receive, at a first position, a transmitting antenna, and an electromagnetically reflective structure arranged at or integrally formed with a first wall among the plurality of walls. The structure is arranged along a shortest path from the first position to a plane in which said first wall extends and is configured to substantially prevent a direct reflection of electromagnetic waves, originating from the first position and incident on the structure, back to the first position.

The Applicant has found that a direct reflection from the transmitting antenna, when arranged at the first position, back to the transmitting antenna via one of the plurality of walls, may influence the accuracy of measurement. In particular, a transmitting antenna typically forms part of an antenna system which also comprises an amplifier. Electromagnetic waves received back by the transmitting antenna may be propagated in part to the output of the amplifier and may cause undesirable loading of the amplifier.

Since directly reflected (i.e., only once reflected) electromagnetic waves will typically have a larger amount of energy than indirectly reflected (i.e., reflected more than once) electromagnetic waves, the unstirred energy component received back at the first position may largely be caused by direct reflections. By arranging a structure along a shortest path from the first position to a plane in which said first wall extends, an otherwise direct reflection from said first wall can be substantially prevented or at least in part mitigated. In other words, an unstirred energy component received back at the first position (i.e., the transmitting antenna) can be significantly reduced using the structure according to the present disclosure.

Furthermore, the structure may render the orientation of the transmitting antenna independent or less dependent on the geometric configuration of the reverberation chamber. By extension, this allows the use of less directional antennas or antennas with configurable directionality (e.g., phased array antennas) over a wide range of angles, without or with hardly any compromise on measurement accuracy. Put differently, the structure according to the present disclosure obviates the need to adjust an orientation of the antenna based on beam angle to be measured, which adjustment itself could also cause a measurement error and may also increase the overall measurement time.

The structure may be positioned at a position where the plane in which the first wall extends is orthogonal to a path from the first position to said plane. Alternatively, the structure may be positioned at a position where a normal vector of the plane extends through the first position.

In an example, the structure may be configured to reduce a total energy directly reflected back to the first position via the structure by at least 90% with respect to what would be reflected back by a substantially flat surface extending in the plane in which said first wall extends and having a same reflection coefficient as the structure. In a preferred embodiment, the reduction of energy reflected back to the first position via the structure is at least 95% or even at least 99%.

In so far as the structure is arranged at the first wall, the first wall may be a substantially planar surface and the structure extends between said planar surface and the first position. In a further embodiment, the plurality of walls may each be substantially planar to form a substantially cuboid or box-shaped chamber volume. Alternatively, in so far as the structure is integrally formed with the first wall, the first wall may be shaped or formed (i.e., may not be planar) to thereby integrally form the structure with the first wall, the structure extending towards the first position. In a further embodiment, walls not having a structure arranged thereon may be substantially planar and the chamber volume may deviate from a cuboid or box shape due to the structure.

The structure may extend towards the first position with respect to the plane in which the first wall extends. Put differently, the structure may include at least one surface that is not parallel to the plane in which the first wall extends.

The structure may be arranged such that, for substantially any angle of propagation of electromagnetic waves within an angular range of at least 45 degrees with respect to a central axis extending from the first position, a direct reflection of electromagnetic waves back to the first position is substantially prevented. In other words, throughout an entire scan range of at least 45 degrees of a transmitting antenna with respect to its central axis, when arranged at the first position in a particular orientation, the structure prevents or at least mitigates reflections of electromagnetic waves originating from the first position and incident on the structure back to the first position.

The structure may comprise one or more convex shapes. For example, the convex shape(s) may be pyramidal, each including a plurality of oblique side surfaces with respect to the plane in which the first wall extends. In a further embodiment, an angle of the side surfaces with respect to the plane in which the first wall extends may lie in a range between 10-80 degrees, preferably between 20-50 degrees, such as about 25 degrees. The Applicant has found that a pyramidal shape of the structure, or as a sub-structure of the structure when comprising a plurality of shapes, is particularly effective at preventing or at least mitigating direct reflections from the transmitting antenna back to the transmitting antenna. Moreover, pyramidal shapes, when provided separately from the first wall, can be manufactured easily by combining a plurality of flat surfaces and mutually fixing them, for example by welding, to form the pyramidal shape. Another manufacturing method is to press the structure out of a metal sheet using a mold.

The structure may additionally or alternatively comprise one or more concave shapes. For example, the concave shape or shapes may include one or more curved surfaces oblique with respect to the plane in which the first wall extends. Such curved surfaces may for example have a parabolic-like curvature, an elliptical curvature, or the like.

Alternatively to the above, the structure may comprise a metamaterial configured to reflect electromagnetic waves, originating from the first position and incident on the structure, away from the first position. For example, the structure may be arranged to extend parallel to the plane in which the first wall extends, and the metamaterial may be configured such that, for electromagnetic waves perpendicularly incident on the metamaterial, an angle of reflection is different from an angle of incidence.

The structure may be arranged with respect to the first position and with respect to the plurality of walls such that the structure is further configured to substantially prevent one or more indirect reflections of electromagnetic waves originating from the first position back to the first position via the structure and one or more of the plurality of walls. In other words, the structure may be designed taking into account not only direct reflections via the structure, but also indirect reflection(s) via the structure as well as one or more of the plurality of walls. This further reduces a component of unstirred energy at the transmitting antenna when positioned at the first position.

The first position may correspond to a position from which electromagnetic waves are effectively radiated by the transmitting antenna at least during operation.

The chamber volume may comprise a plurality of said first positions together defining a first positioning space where the transmitting antenna can be received. In that case, the structure may be arranged along a shortest path from each first position to a plane in which said first wall extends, and may be configured to reflect at least part of electromagnetic waves originating from respective first positions and incident on the structure, away from said respective first positions. In other words, the structure may be designed not only with a specific position in mind but a volume of positions where the transmitting antenna can be positioned.

In a further embodiment, the structure may be further configured to reflect at least part of electromagnetic waves originating from the first positioning space and incident on the structure away from said first positioning space. Rather than accounting for reflections of electromagnetic waves per first position in the first positioning space, the structure may be designed taking into account the first positioning space as a whole and may prevent or mitigate direct reflections originating from any position in the first positioning space back to the first positioning space via the structure.

The chamber volume may be further configured to receive, at a second position, a receiving antenna configured to receive electromagnetic waves. That is, there may be a second position (or second positioning space) within the chamber volume designated to receive the receiving antenna.

In a further embodiment, the reverberation chamber may further comprise an electromagnetically reflective shielding element arranged between the first position and the second position to prevent a line-of-sight path of electromagnetic waves between the first position and the second position. Since a line-of-sight path from the first position or first positioning space to the second position or second positioning space would result in a relatively large unstirred energy component at the receiving antenna, potentially influencing a measurement, the shielding element is provided in said path such as to prevent this unstirred energy component. Of course, care can be taken to prevent direct reflections of electromagnetic waves from the first position back to the first position via the shielding element by shaping and/or orientating the shielding element accordingly. The reverberation chamber may further comprise one or more electromagnetically reflective mode stirring units arranged in the chamber volume and configured to be adjustable between a plurality of mode stirring states, corresponding to different positions and/or orientations of said one or more stirring units or otherwise configurable reflective states thereof, to thereby change a reflection behavior of electromagnetic waves within the chamber volume. As will be appreciated by the skilled person, the one or more mode stirring units can be used to stir energy in the chamber volume by reflecting electromagnetic waves differently between the plurality of mode stirring states.

Alternatively, or additionally, position stirring can be applied. For example, instead (or in addition) to the plurality of mode stirring states, the position and/or orientation of the transmitting antenna inside the chamber volume is adjusted, thereby probing at different locations and effectively providing a plurality of further mode stirring states. To that end, the reverberation chamber may further comprise an adjustment element, such as a movable platform, configured to move the transmitting antenna, when arranged in the chamber volume, between a plurality of position stirring states, corresponding to different positions and/or orientations of the transmitting antenna, to thereby sample the field at different locations within the chamber volume. The present disclosure can be applied to mode stirring using mode stirring units, using position stirring, or both. The reverberation chamber may comprise a plurality of said structures arranged on or integrally formed with respective walls among the plurality of walls. That is, there may be multiple positions on multiple respective walls where a structure is arranged for preventing or mitigating direct reflections. This may for example be relevant when the transmitting antenna is oriented to roughly face multiple walls among the plurality of walls, and where direct reflections could otherwise occur from multiple walls withing the scan range of the antenna. By providing multiple structures at respective walls, these direct reflections can be substantially prevented or mitigated.

In a further embodiment, the plurality of structures may form an integral structure.

The plurality of walls may be substantially orthogonal. Put differently, each wall of the plurality of walls may be planar and perpendicular to adjacent walls among the plurality of walls. The reverberation chamber may be configured to be used at an operating frequency in a range between in a range between 0.2-1000 GHz, preferably 30-300 GHz. In a further embodiment, the structure may be spaced apart from the first position by at least 1 wavelength at said operating frequency. In a further embodiment, the structure may be spaced apart by at least 30 wavelengths or even at least 50 wavelengths.

The first position may be further removed from the first wall than from a second wall among the plurality of walls opposite to the first wall.

The plurality of walls and the structure may be made of, or coated by, a conductive metal or metal alloy, preferably one of copper, aluminum, aluminum chromate, stainless steel, and gold. However, the present disclosure is not limited thereto, and any highly conductive material other than those listed above could be used instead to form or coat the structure.

At least one of the plurality of walls may be provided with an opening allowing access to the chamber volume. Furthermore, the reverberation chamber may further comprise a closing element configured to be movable between an open position in which the opening is exposed and a closed position in which the opening is obstructed by the closing element. The closing element may comprise an electromagnetically reflective inner surface facing the chamber volume when the closing element is in the closed position.

The reverberation chamber may further comprise a contact arranged in the chamber volume and configured to be electrically connected to the transmitting antenna at least during operation, and a connecting element electrically connected to the contact and extending to an exterior of the chamber volume for enabling external electrical access to the contact. The first position may be at or near a position of the contact in the chamber volume.

The reverberation chamber may comprise the transmitting antenna arranged at the first position, and the transmitting antenna may be an autonomous emitter.

According to another aspect of the present disclosure, a measurement system is provided, comprising the reverberation chamber according to any of the embodiments described above in so far as having one or more mode stirring units, a transmitting antenna arranged at the first position, a receiving antenna arranged in the chamber volume, and a control unit configured to perform a measurement of at least one characteristic of the transmitting antenna or the receiving antenna using a signal received from the receiving antenna based on electromagnetic waves received by the receiving antenna.

The control unit may be configured to perform the measurement by performing a plurality of sub-measurements and combining a result thereof. During each sub-measurement, the one or more mode stirring units may be in different respective mode stirring states among the plurality of mode stirring states.

The transmitting antenna may be a phased-array antenna configured to emit and steer a main beam of electromagnetic waves in one of a plurality of possible directions based on a control signal. The control unit may be configured to perform a plurality of said measurements. For each measurement, the control unit may control the transmitting antenna using the control signal to steer the main beam a different respective direction.

The measurement system may comprise a power detector, spectrum analyzer and/or a vector network analyzer (VNA) electrically connected to the receiving antenna for performing the measurement. If a VNA is used, the VNA may also be electrically connected to the transmitting antenna.

The at least one characteristic may comprise at least one of a total radiated power of the transmitting antenna, a radiation pattern of the transmitting antenna and/or the receiving antenna, and a noise figure of the receiving antenna. However, the present disclosure is not limited thereto, and other metrics or characteristics of the transmitting antenna and/or receiving can be measured or determined using the reverberation chamber according to the present disclosure, as will be appreciated by the skilled person.

According to another aspect of the present disclosure, an assembly is provided comprising the reverberation chamber described above, a transmitting antenna, and a receiving antenna.

Next, the present invention will be described in more detail referring to the appended drawings, wherein:

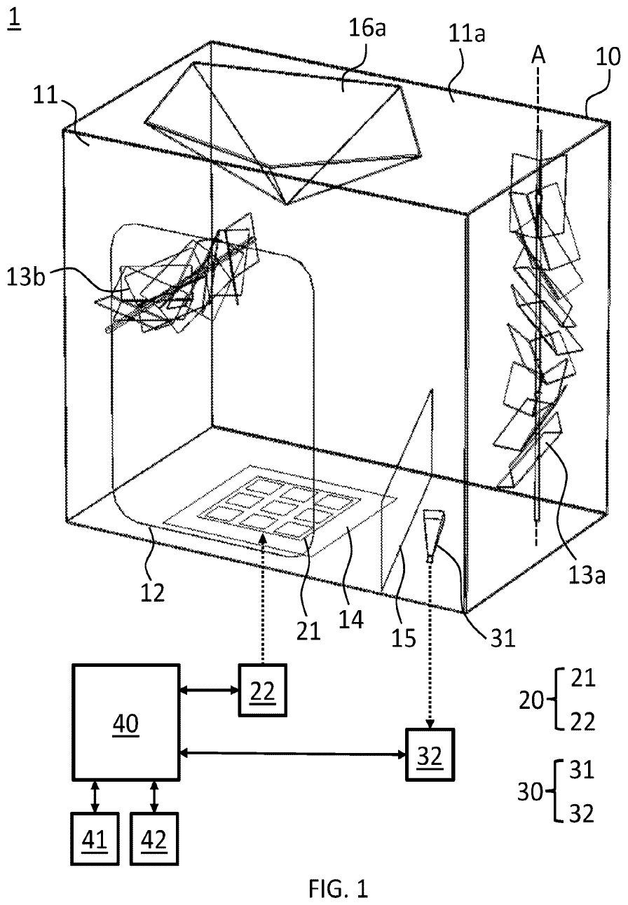

FIG. 1 is a perspective view of a reverberation chamber according to an embodiment of the present disclosure;

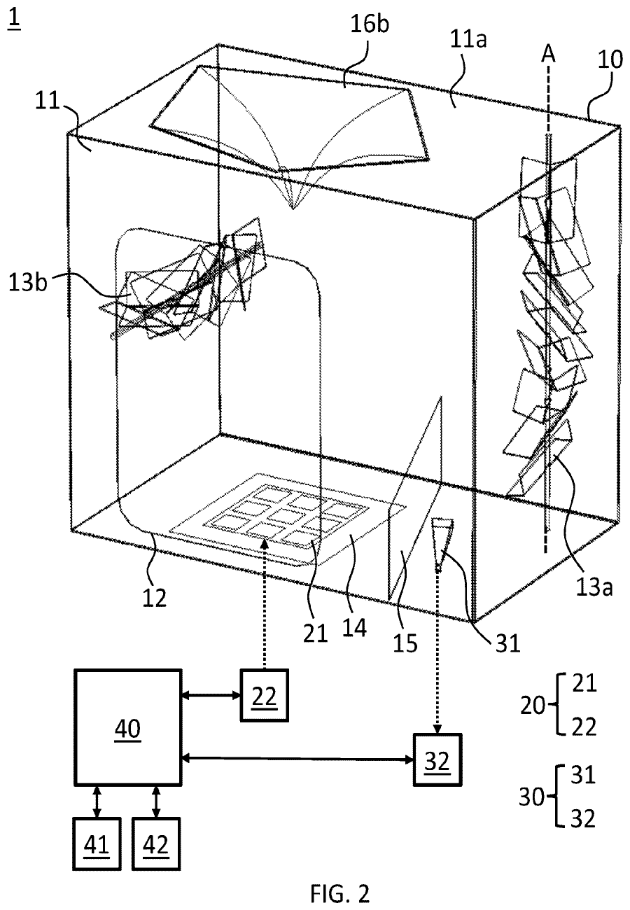

FIG. 2 is a perspective view of a reverberation chamber according to another embodiment of the present disclosure;

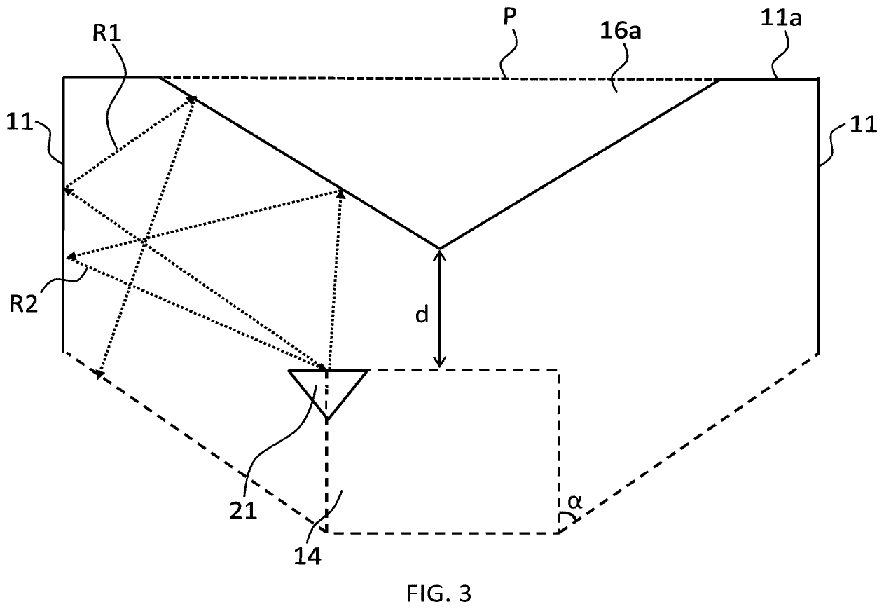

FIG. 3 is a simplified cross-sectional view of part of the reverberation chamber of FIG. 1;

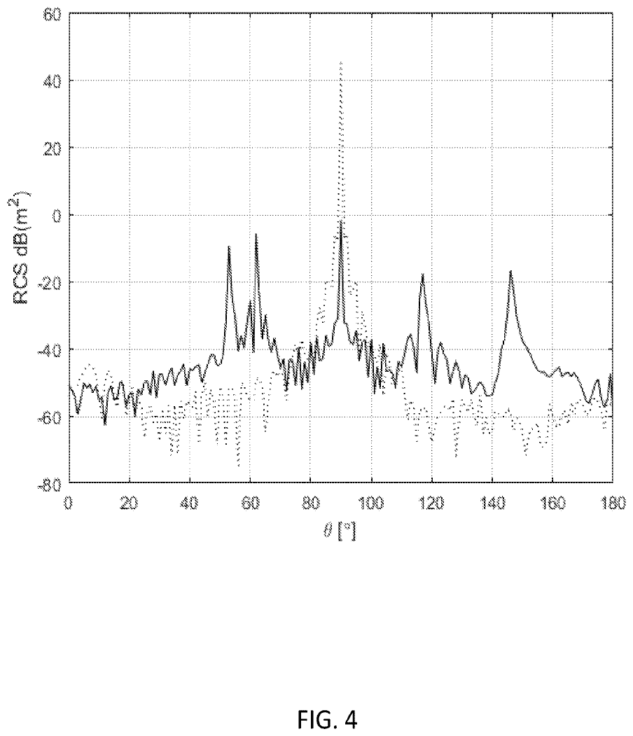

FIG. 4 is a graph illustrating a radar cross section (RCS) simulation of a structure according to the present disclosure, and of a planar surface; and

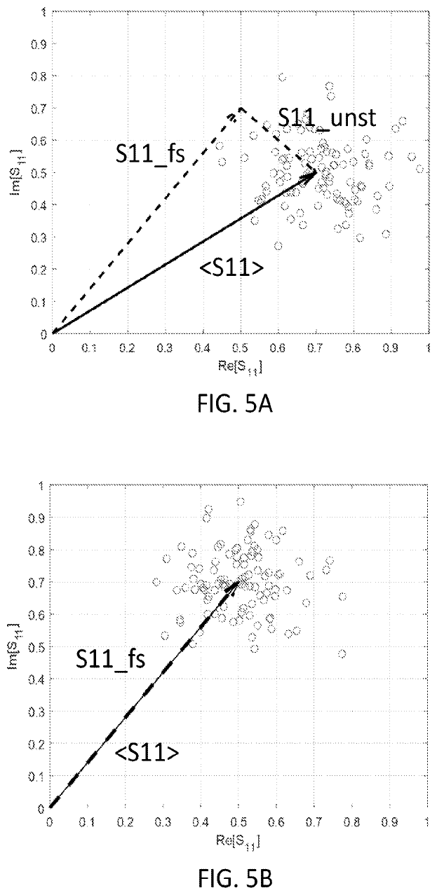

FIGS. 5A and 5B are simulated examples of S11-measurements of a transmitting antenna in a reverberation chamber without a structure according to the present disclosure, and with such a structure, respectively.

Hereinafter, reference will be made to the appended drawings. It should be noted that identical reference signs will be used to refer to identical or similar components. Moreover, unless explicitly stated otherwise, various elements shown in the appended drawings may not be drawn to scale, and parts may be exaggerated or omitted for convenience of explanation.

In FIG. 1, a measurement system 1 according to an embodiment of the present disclosure is shown. Measurement system 1 comprises a reverberation chamber 10, a transmitting antenna 21, a receiving antenna 31, and a control unit 40. Although not illustrated in the figures, in some embodiments, measurement system 1 may comprise more than one transmitting antenna 21 and/or more than one receiving antenna 31.

Reverberation chamber 10 comprises a plurality of electromagnetically reflective walls 11 together defining (i.e., enclosing) a chamber volume. One of walls 11 is provided with an opening 12 for allowing access to the chamber volume. For example, transmitting antenna 21 and receiving antenna 31 may be arranged in or removed from the chamber volume through opening 12.

Reverberation chamber 10 may further comprise mode stirring units 13a, 13b arranged in the chamber volume and configured to be adjustable between a plurality of mode stirring states providing different reflective behaviors within the chamber volume. In other words, mode stirring units 13a, 13b may be movable (e.g., translatable), rotatable, or may have otherwise configurable reflective states, thereby changing a reflective behavior within the chamber volume. In the embodiment shown in FIG. 1, for example, mode stirring unit 13b may be rotatable around an axis A, and mode stirring unit 13a may similarly be rotatable around its axis (not indicated). As illustrated in FIG. 1, mode stirring units 13a, 13b include a plurality of electromagnetically reflective surfaces at various relative angles. Typically, these surfaces may be formed as V-shapes, U-shapes, W-shapes, Z-shapes (e.g., in Z-fold stirrers), or the like. In some embodiments, the relative angles of the surfaces of mode stirring units 13a, 13b may instead or additionally be configurable.

Within the context of the present disclosure, otherwise configurable reflective states of the one or more mode stirring units 13a, 13b may refer to changing a mode stirring state without physically moving mode stirring units 13a, 13b. For example, electronic mode stirring units 13a, 13b comprising a plurality of tunable lumped elements such as diode varactors may be used. In that case, rather than moving mode stirring units 13a, 13b, a reflective behavior of mode stirring units 13a, 13b can be configurable by an electric signal. Although only two mode stirring units 13a, 13b are shown in FIG. 1, the present disclosure does not exclude reverberation chambers with one mode stirring unit or with more than two mode stirring units.

Transmitting antenna 21 may be comprised in a transmitting system 20, further including transmitting circuitry 22 such as a radiofrequency (RF) amplifier (e.g., a power amplifier), transmission lines or other types of electrical connections, a mixer, an oscillator, or the like, for the purpose of generating and providing an RF signal for transmitting antenna 21. Here, transmitting antenna 21 may be an antenna array or phased array including a plurality of antenna elements. As will be appreciated by the skilled person, such antennas may be configurable in terms of radiation pattern, such as a direction of a main beam of radiation from transmitting antenna 21, by providing the plurality of antenna elements with respective signals accordingly. As such, a scan range can be defined with respect to a central axis of transmitting antenna 21 including a plurality of angles towards which a peak of the main beam can be directed electronically. Typical scan ranges may be in a range between 45-70 degrees relative to the central axis (e.g., “boresight”) or, in other words, a cone with an angle of 90-140 degrees with respect to transmitting antenna 21. However, the present disclosure is not limited thereto, and the scan range of transmitting antenna 21 relative to the central axis may similarly be less than 45 degrees or more than 70 degrees.

Receiving antenna 31 may be comprised in a receiving system 30, which may further include receiving circuitry 32, such as an RF amplifier (e.g., a low-noise amplifier (LNA)), transmission lines or other types of electrical connections, or the like, for the purpose of receiving a signal from receiving antenna 31. Receiving antenna 31 may be a passive antenna, such as a horn antenna as shown in FIG. 1, in which case some elements of receiving circuitry 32 may be omitted. Moreover, receiving antenna 31 may have a relatively high directionality and may be oriented obliquely facing a wall among the plurality of walls 11. Ideally, receiving antenna 31 is oriented with respect to transmitting antenna 21 in a manner that prevents or at least mitigates direct reflections (i.e., a large unstirred energy component) from being received by receiving antenna 31. For example, receiving antenna 31 may be oriented such that a maximum in the radiation pattern of receiving antenna 31 is not aligned with a path of a direct reflection of an electromagnetic wave originating from transmitting antenna 21 (or first positioning space 14 as a whole).

For some measurements, a functionality of transmitting antenna 21 and receiving antenna 31 may be swapped. For example, transmitting system 20 may form part of a first transceiver system (not shown) and receiving system 30 may form part of a second transceiver system (not shown) different from the first transceiver system. In that case, transmitting antenna 21 can be used to receive electromagnetic waves instead, and receiving antenna 31 can be used to emit electromagnetic waves instead. To that end, transmitting antenna 21 may be a first transceiver antenna and receiving antenna 31 may be a second transceiver antenna. However, a position of structure 16a may still be defined with respect to transmitting antenna 21 (or first positioning space 14 as a whole).

In some embodiments, transmitting antenna 21 is movably arranged in reverberation chamber 10. For example, transmitting antenna 21 may be rotatable or translatable through the use of a controllable movable platform (not shown) arranged in reverberation chamber 10. This may for example be used to implement position stirring, i.e., sampling the field in the chamber volume at different positions.

Measurement system 1 further comprises a control unit 40 configured to control various components of measurement system 1. For example, control unit 40 may control transmitting antenna 21 via transmitting circuitry 22 to emit electromagnetic waves in the chamber volume.

Control unit 40 may also control mode stirring units 13a, 13b to change a mode stirring state thereof, for example by actuating a motor to rotate or move mode stirring units 13a, 13b or by providing an electrical signal to mode stirring units 13a, 13b to configure a reflective state thereof. In some embodiments, control unit 40, or at least part of a functionality thereof, may be comprised in reverberation chamber 10.

Control unit 40 may be further configured to receive a signal from receiving antenna 31, for example via receiving circuitry 32, for the purpose of performing a measurement to determine at least one characteristic of transmitting antenna 21 and/or receiving antenna 31. To that end, measurement system 1 may further comprise means for performing said measurement. For example, the means may include at least one of a power detector, a vector network analyzer (VNA) 41, a spectrum analyzer (SA) 42, or the like. In some embodiments, control unit 40, VNA 41 and SA 42 are integrated in a single measurement module, though this does not need to be the case.

As will be appreciated by the skilled person, typical characteristics of antennas that can be determined using measurement system 1 (i.e., with a reverberation chamber) may include a total radiated power (TRP) of transmitting antenna 21, a radiation pattern of transmitting antenna 21 and/or receiving antenna 31, a noise figure of receiving antenna 31, and various other characteristics of either or both of transmitting antenna 21 and receiving antenna 31.

In some measurements, a functionality of transmitting antenna 21 and receiving antenna 31 may be swapped. For example, transmitting antenna 21 may be configured to receive instead of transmit, and receiving antenna 31 may be configured to transmit instead of receive. To that end, transmitting system 20 may form part of a first transceiver system (not shown), and receiving system 30 may form part of a second transceiver system (not shown). However, the structure according to the present disclosure (e.g., structure 16a) remains positioned with respect to the first position, corresponding to transmitting antenna 21.

A first positioning space 14 is defined in the chamber volume where transmitting antenna 21 can be arranged. For example, first positioning space 14 includes a plurality of first positions where transmitting antenna 21 (e.g., a center thereof) can be arranged. Similarly, although not shown in FIG. 1, a second positioning space may be defined in the chamber volume where receiving antenna 31 can be arranged. A shielding element 15 may be provided between transmitting antenna 21 and receiving antenna 31 (i.e., between first positioning space 14 and the second positioning space) during measurement, or may be fixedly provided in reverberation chamber 10.

At or near first positioning space 14, a contact (not shown) may be provided configured to be electrically connected to transmitting antenna 21 at least during operation. The contact may furthermore provide an interconnection between transmitting antenna 21 and at least part of transmitting circuitry 22, or may itself be part of transmitting circuitry 22. To that end, a connecting element, for example also comprised in transmitting circuitry 22, may provide a connection from transmitting antenna 21 (e.g., from the contact) to an exterior of reverberation chamber 10. First positioning space 14 may at least to some extent be limited by a position of such contact and connecting element. Transmitting circuitry 22 may also include various other components such as a data and/or power connection for transmitting antenna 21.

In some embodiments, transmitting antenna 21 may be an autonomous emitter, such as a mobile phone, for example. In that case, transmitting antenna 21 may be configured to emit electromagnetic waves into the chamber volume without requiring electrical access to transmitting antenna 21 from outside reverberation chamber 10. For example, part of transmitting circuitry 22 such as the above-described contact, connecting element, and/or various other elements may be omitted, as will be appreciated by the skilled person.

Reverberation chamber 10 further includes an electromagnetically reflective structure 16a arranged on or integrally formed with a first wall 11a among the plurality of walls 11. Moreover, structure 16a may be arranged along a shortest path from first positioning space 14 to a plane in which first wall 11a extends. In doing so, structure 16a is arranged at a position where, with respect to first positioning space 14, direct reflections could otherwise occur.

Structure 16a may be mounted on or otherwise fixed with respect to first wall 11a.

Alternatively, structure 16a may be integrally formed with first wall 11a. In so far as structure 16a is arranged at (e.g., mounted on or attached to) first wall 11a, first wall 11a may be a planar surface, such as a metal plate. Preferably, in this embodiment, each wall among the plurality of walls 11 are substantially planar surfaces together defining a box-shaped, i.e., substantially cuboid chamber volume. In that case, structure 16a is arranged in said chamber volume and extends from said planar surface of first wall 11a towards the first position or first positioning space 14. On the other hand, if structure 16a is integrally formed with first wall 11a, then first wall 11a may not be entirely planar but may instead be shaped or formed to provide structure 16a therein. That is, the chamber volume, at least due to structure 16a, may deviate from a substantially cuboid shape.

Moreover, when structure 16a is integrally formed with first wall 11a, structure 16a may also extend away from the first position (or first positioning space 14), i.e., in an outward direction.

Structure 16a is configured to reflect at least part of electromagnetic waves originating from a first position of first positioning space 14 and incident on structure 16a away from said first position. Preferably, structure 16a is configured to reflect at least part of electromagnetic waves originating from anywhere in first positioning space 14 and incident on structure 16a away from first positioning space 14 as a whole. By arranging and shaping structure 16a accordingly, electromagnetic waves emitted from transmitting antenna 21, when arranged in first positioning space 14, are not reflected back to transmitting antenna 21 by structure 16a or at least to a lesser extent. Preferably, structure 16a substantially prevents any direct reflection, and optionally one or more indirect reflections, of electromagnetic waves originating from transmitting antenna 21 back to transmitting antenna 21, and should be designed accordingly. Put differently, structure 16a may be configured to substantially scatter electromagnetic waves, or at least partially scatter, originating from the first position and incident on the structure, away from the first position.

As shown in FIG. 1, structure 16a may have a convex shape, such as a pyramidal shape.

The pyramidal shape may include a plurality of oblique side surfaces extending from a base of the pyramidal shape, wherein the side surfaces are oblique with respect to the plane in which first wall 11a extends. Structure 16a may have five side surfaces as illustrated in FIG. 1, though structures with less than five or more than five are equally envisaged. Said side surfaces may be integrally formed or may be joined together, for example through a welding process. Preferably, structure 16a is formed as an irregular or asymmetric pyramid, where angles between adjacent side surfaces and/or dimensions of each side surface may not be identical.

Although not shown in FIG. 1, structure 16a may comprise more than one convex shape in accordance with the above. For example, structure 16a may comprise a plurality of adjacently arranged sub-structures (not shown). The sub-structures may be integrally formed, mutually fixed, or provided separately without a joint. Said sub-structures may each have a convex shape and more in particular may each have a pyramidal shape, though the present disclosure is not limited thereto. The sub-structures need not be identical. For example, the number of side surfaces, the dimensions of the shape, or even the type of shape may differ between sub-structures. For example, one or more sub-structures may have a pyramidal shape, and one or more further sub-structures may have a different shape, such as a round or elliptical shape, another convex shape, a concave shape, or the like.

It should be noted that the pyramidal shape(s) described above, although found by the applicant to be highly suitable for mitigating direct reflections, are of exemplary nature. The present disclosure is not limited to a specific convex shape such as pyramidal shapes, and other convex shapes can be envisaged without departing of the scope of the present disclosure.

In practice, joints between side surfaces of structure 16a, a slightly blunted peak of the pyramidal shape as shown in FIG. 1, or other surface imperfections may cause structure 16a to directly reflect a small amount of energy of electromagnetic waves incident thereon back to transmitting antenna 21. However, direct reflections back to transmitting antenna 21 due to such imperfections may be relatively small with respect to direct reflections in conventional reverberation chambers. Measurements performed using reverberation chamber 10 according to the present disclosure can be only minorly or negligibly influenced by such reflections.

For example, structure 16a may be configured to reduce the energy directly reflected back to transmitting antenna 21 by at least 90%, preferably at least 95% or even at least 99%, with respect to what a surface parallel to the plane in which first wall 11a extends would reflect back, assuming an substantially identical or similar reflectance.

To cover a broad range of angles, for example for testing phased array antennas of which a directionality is configurable, transmitting antenna 21 is ideally oriented facing structure 16a, such that a default direction of a main beam thereof is directed at structure 16a. For example, as shown in FIG. 1, structure 16a is arranged at or near first wall 11a, and transmitting antenna is arranged further from first wall 11a than from a second wall opposite first wall 11a with the antenna elements facing structure 16a. In that case, direct reflections at or near first wall 11a are substantially prevented by structure 16a, and the scan range with respect to transmitting antenna 11a (i.e., with respect to first positioning space 14) in which no or hardly any direct reflections occur can be extended up to 180 degrees. In some embodiments, transmitting antenna 21 is arranged off-center with respect to structure 16a. Put differently, a center of transmitting antenna 21 may not be directly facing a center of structure 16a. This can allow a user of reverberation chamber 10 to position transmitting antenna 21 faster and more easily, provided that it is within first positioning space 14 where structure 16a prevents direct reflections from first wall 11a.

Although not shown in FIG. 1, reverberation chamber 10 may comprise a plurality of structures in accordance with the present disclosure, such as structure 16a. Each of said plurality of structures may be arranged on or integrally formed with a respective wall among plurality of walls 11 of reverberation chamber 10, and may be arranged along a shortest path from first positioning space 14 to said respective wall. In doing so, direct reflections can be substantially prevented for multiple walls among the plurality of walls 11. Furthermore, this may offer more freedom regarding an orientation of transmitting antenna 21 in the chamber volume. For example, when transmitting antenna is oriented to face multiple walls 11 of reverberation chamber 10 at an oblique angle, such as towards a position at or near an edge between two walls, multiple structures such as structure 16a may be provided for each of said walls to prevent or mitigate direct reflections from said walls.

Reverberation chamber 10 may comprise a door, hatch, or the like (not shown) arranged to fit opening 12 and to isolate the chamber volume from an exterior of reverberation chamber 1. The door may be movable between an open position and a closed position. In the open position, at least part of opening 12 is not obstructed by the door. In the closed position, opening 12 is obstructed by the door. For example, the door may have an electromagnetically reflective inner surface arranged to face the chamber volume when the door is in the closed position. For convenience of illustration, the door of reverberation chamber 10 is omitted from FIG. 1.

The suitable dimensions of reverberation chamber 10 and structure 16a may depend at least partially on the operating frequency of transmitting system 20 and receiving system 30, i.e., the frequency of electromagnetic waves to be reflected in chamber volume. For example, lower frequencies may require a larger reverberation chamber, whereas smaller reverberation chambers may be better suited for higher frequencies.

Typical dimensions of reverberation chamber 10 at an operating frequency in the range between 20-140 GHz may be in the order of 1 m 3 or less, for example 0.8×0.5×0.65 m (length×width×height). Structure 16a may extend from the plane in which first wall 11a extends towards first positioning space 14 by a certain amount, for example 10%-30% of the height of reverberation chamber 10, for example 0.15 m assuming the above dimensions of reverberation chamber 10. As an example, first positioning space 14 may have dimensions of roughly 0.2'0.2'0.2 m (length×width×height). Furthermore, viewed in a direction perpendicular to the plane in which first wall 11 a extends, structure 16 a may have a projected area of 0.02-0.4 m². Angles of the side surfaces of structure 16 a with respect to its base may be in a range of 10-80 degrees, such as 25 degrees. It should be noted that the dimensions given here are of exemplary nature and that the present disclosure is not limited to any particular dimensions.

In FIG. 2, measurement system 1 is shown in accordance with another embodiment of the present disclosure. A detailed description of elements already described with reference to FIG. 1 is omitted.

Here, reverberation chamber 10 comprises a structure 16b instead of structure 16a of FIG. 1. As an example, structure 16b may have a concave shape, having one or more surfaces oblique to the plane in which first wall 11a extends. As shown in FIG. 2, the one or more surfaces may be curved and may have a parabolic curvature, an elliptical curvature, a circular curvature, or the like. Although not shown in FIG. 2, in some embodiments, structure 16b may comprise a plurality of sub-structures, for example having one or more structures shaped identically or similarly to structure 16b, and one or more other types of shapes, such as the pyramidal shape of structure 16a as shown in FIG. 1.

Other than the shape, the description for structure 16a with reference to FIG. 1 may equally apply to structure 16b of FIG. 2 or other structures in accordance with the present disclosure having respective shapes that are included in the scope of the present disclosure.

Instead of structure 16a as shown in FIG. 1 or structure 16b as shown in FIG. 2, in which surfaces of the structure are arranged at an angle with respect to the plane in which first wall 11 extends, the use of a metamaterial configured to reflect at least part of electromagnetic waves, originating from the first position (or first positioning space 14) and incident on said metamaterial, away from said first position (or first positioning space 14).

For example, such a structure, although not shown in the figures, may be a surface made of a metamaterial which prevents or at least mitigates that an angle of reflection extends towards the first position (or first positioning space 14) for at least some but preferably most or all possible angles of incidence originating from the first position (or first positioning space 14). In a further example, where such metamaterial surface is arranged in parallel to the plane in which first wall 11a extends, an angle of incidence may not equal an angle of reflection for normal incidence, i.e., 90 degrees. In some embodiments, the metamaterial surface may be configurable.

The metamaterial surface may also be combined with any of the embodiments shown in FIG. 1 and FIG. 2. For example, one or more sub-structures may comprise said metamaterial surface, and/or at least one of a plurality of structures for respective walls may comprise said metamaterial surface.

As an example only, the metamaterial may be an anomalous reflecting meta-surface, which may have the property that angle of incidence does not equal angle of reflection for some angles of incidence. Such a meta-surface is for example known from “Broadband anomalous reflection based on gradient low-Q meta-surface” by M. Pu et al.

As another example, the metamaterial may be a (beam-refracting) Huygens' meta-surface, for example as described in “Metamaterial Huygens' Surfaces” by C. Pfeiffer and A. Grbic. With such a material, angle of reflection may be different from angle of incidence when the angle of incidence is 90 degrees (i.e., normal incidence). Hence, by arranging said metamaterial facing transmitting antenna 21, direct reflections back to transmitting antenna 21 can be substantially prevented. Said metamaterial may be mounted on first wall 11 and may optionally be backed with an electromagnetically reflective (e.g., metal) plate. For example, if said metamaterial is integrated into first wall 11, the plate may ensure that leakage of electromagnetic waves out of reverberation chamber 10 is prevented or at least mitigated.

Both types of the above-described meta-surfaces can be constructed in a similar fashion.

Typically, they comprise sub-structure which are a fraction of the wavelength in size at the operating frequency and placed in a 2D plane. Often, though not necessary, said sub-structures are periodically spaced in one or two dimensions. The sub-structures of the meta-surface are typically made of conductive metallic strips, such as copper, gold, or the like, and have a thin low-loss dielectric substrate material.

In FIG. 3, a simplified cross-sectional view of reverberation chamber 10 of FIG. 1 is shown. In particular, FIG. 3 illustrates first wall 11a, part of two other walls 11, first positioning space 14, transmitting antenna 21, and structure 16a. A scan range with respect to first positioning space 14 is indicated using angle a, representing a maximum angle with respect to a central axis (e.g., “boresight”') of transmitting antenna 21 at which a main beam can be directed, and assuming transmitting antenna 21 is oriented perpendicularly facing the plane P in which first wall 11a extends. Structure 16a is spaced apart from first positioning space 14 by a distance d, which may for example be one wavelength or more at the operating frequency of transmitting antenna 21, though this does not necessarily need to be the case. As shown in FIG. 3, structure 16a may extend towards the first position of transmitting antenna 21 (or towards first positioning space 14) with respect to plane P. For convenience of explanation, other elements of reverberation chamber 10 are omitted from FIG. 3.

To establish whether a particular structure is suitable for preventing or mitigating direct reflections, ray tracing may be applied. Ray tracing may also be referred to as geometric optics.

Using ray tracing, it can be assessed whether a ray originating from transmitting antenna 21 can be traced back to transmitting antenna 21 (or to first positioning space 14 as a whole) after one reflection (i.e., direct reflection) and optionally also after two or more reflections (i.e., indirect reflection). If a direct or optionally indirect reflection is traced back to transmitting antenna 21 (or to first positioning space 14 as a whole), structure 16a may have to be adjusted to account for it.

For example, if a fraction of rays that are traced back to transmitting antenna 21 is below a predefined threshold, it may be determined that the structure has a sufficient performance. The performance may be evaluated not only for one position of transmitting antenna 21, but for a plurality of positions of first positioning space 14. In that case, the fraction of rays may be determined across first positioning space 14 as a whole rather than each position individually.

In the cross-section shown in FIG. 3, for example, two different ray paths are indicated with successive dotted arrows. For convenience, it may be assumed that the chamber is open on one end beyond the predetermined scan range, such that any ray exiting the scan range is assumed not to return. First ray R1 exits the scan range after two reflections, whereas second ray R2 is traced back to transmitting antenna 21 after two reflections. However, no direct reflection can be traced back to transmitting antenna 21 (or first positioning space 14 as a whole) in the present example.

In FIG. 4, a graph is shown illustrating a result of a radar-cross-section (RCS) simulation of structure 16a of FIG. 1 with respect to a planar surface, wherein the x-axis illustrates an angle of the source and the y-axis illustrates the resulting RCS. The RCS of structure 16a is indicated with a solid line, and the RCS of the planar surface is indicated with a dotted line.

In the RCS simulation, structure 16a and the planar surface are each simulated to be illuminated in free space with plane waves coming from different angles, and a direct reflection towards the source is determined. This may be referred to as monostatic RCS. The simulated maximum RCS of structure 16a can then be compared to that of the planar surface to verify or further optimize the performance of the designed structure.

The simulated planar surface is given the same dimensions as a projection of structure 16a of FIG. 1 in a direction perpendicular to the plane in which first wall 11a extends.

Furthermore, in the RCS simulation, manufacturing imperfections can be taken into account to gain insight on the practical feasibility of structure 16. For the purpose of illustration, structure 16a is simulated including an imperfection at a peak of the pyramidal shape where the plurality of side surfaces join. In particular, the peak is blunted in the simulation such that an area of roughly 25 mm² at a position of the peak is parallel to the simulated planar surface. For completeness, said blunted area in this simulation corresponds to about 0.02% of the total area of the simulated planar surface, and may be achievable in terms of manufacturability.

As shown in FIG. 4, with a planar surface, a relatively large maximum RCS occurs at an angle of the source of 90 degrees. This result is expected due to normal incidence of the simulated waves on the planar structure. Structure 16a simulated with the abovementioned dimensions offers an improvement of over 45 dB of the maximum RCS with respect to the planar surface. In other words, direct reflection that would occur in absence of structure 16 a is reduced by over 99.99%.

An improvement of at least 10 dB may already be adequate for substantially preventing direct reflections from influencing the measurement accuracy.

In other words, the structure according to the present disclosure (e.g., structure 16a, structure 16b, or the metamaterial described above) may be configured to reduce a maximum RCS by at least 90%, preferably at least 95%, more preferably at least 99%, when compared to a planar surface having a same (or similar) reflectance.

The RCS simulation can also be extended to take into account not only direct reflections but also one or more indirect reflections, by further modelling some of the plurality of walls of the reverberation chamber. However, since indirect reflections typically may have a lower energy, direct reflections will in general have the largest influence on measurement accuracy.

Although simulation results for structure 16a of FIG. 1 are shown in FIG. 4, similar results can be obtained with other structures according to the present disclosure, such as structure 16b, or a meta-surface.

Another way to verify the performance of reverberation chamber 10 is by performing S-parameter measurements on transmitting antenna 21 in absence of and in presence of structure 16a. This is illustrated using FIGS. 5A and 5B.

In FIG. 5A, a scatter plot is shown illustrating a simulation of an S11 parameter of transmitting antenna 21 across a plurality of simulated measurements for each of a plurality of mode stirring states of a reverberation chamber in absence of structure 16a (i.e., with a planar surface such as one of walls 11). Similarly, in FIG. 5B, a scatter plot is shown illustrating a measured S11 parameter of transmitting antenna 21 across a plurality of measurements for each of a plurality of mode stirring states of reverberation chamber 10 including structure 16a. The x-axis represents a real part of the measured $11, and the y-axis represents an imaginary part of the measured S11. In each of FIG. 5A and FIG. 5B, a total of 100 S11-parameter measurements are shown.

Furthermore, arrows (vectors) are drawn representing a calculated S11 (<S11>) corresponding to an average of the performed measurements, a known S11 of transmitting antenna 21 in free space (S11_fs), and a difference (S11_unst) between <S11>and S11_fs. For example, S11_fs of transmitting antenna S11 itself may be based on a measurement of transmitting antenna 21 in an anechoic chamber.

Direct reflections are typically the largest contributor to unstirred energy, due to the relatively short traversed path by the corresponding electromagnetic waves compared to indirect reflections. In absence of structure 16a, a direct reflection from one of the walls of the reverberation chamber may be present in each of the plurality of measurements, since the mode stirring states do not affect this (static) component. When the direct reflection is received back by transmitting antenna 21, this component is reflected in the <S11>.

In a single measurement, stirred energy and unstirred energy cannot be distinguished.

However, across a plurality of measurements, as shown in FIG. 5A, <S11>is shifted with respect to S11_fs. The difference between the <S11>and S11_fs represents a mean shift due to unstirred energy, as this unstirred energy component is present in each measurement.

Referring now to FIG. 5B, when structure 16a is present, the <S11>is significantly closer to S11_fs and may almost coincide. For convenience of illustration, S11_unst is not illustrated in FIG. 5B. This measurement result may be indicative of a significantly reduced unstirred energy component due to the prevention or mitigation of direct reflections back to transmitting antenna 21. A magnitude of the determined S11_unst when structure 16a is included can be compared to a magnitude of the determined S11_unst when structure 16a is omitted to verify the performance improvement. For example, as a performance metric, structure 16a may be designed such that a ratio of maximum S11_unst with structure 16a and maximum S11_unst without structure 16a across a predefined scan range of transmitting antenna 21 may be −10 dB or less, depending on the application.

The above may be repeated for a plurality of beam angles of transmitting antenna 21 to verify an overall performance of reverberation chamber 10 across an angular scan range, to verify that direct reflections do not or hardly occur at any angle within said scan range.

The present disclosure may further relate to any of the following clauses.

Clause 1. A reverberation chamber for testing an antenna, comprising: a plurality of electromagnetically reflective walls together defining a chamber volume, the chamber volume being configured to receive, at a first position, a transmitting antenna; and an electromagnetically reflective structure arranged at or integrally formed with a first wall among the plurality of walls, wherein the structure is arranged along a shortest path from the first position to a plane in which said first wall extends and is configured to reflect at least part of electromagnetic waves, originating from the first position and incident on the structure, away from the first position.

Clause 2. The reverberation chamber according to clause 1, wherein: in so far as the structure is arranged at the first wall, the first wall is a substantially planar surface and the structure extends between said planar surface and the first position; or in so far as the structure is integrally formed with the first wall, the first wall is shaped or formed to thereby integrally form the structure with the first wall, the structure extending towards or away from the first position.

Clause 3. The reverberation chamber according to clause 1 or 2, wherein the structure is positioned at a position where the plane in which the first wall extends is orthogonal to a path from the first position to said plane, or wherein the structure is positioned at a position where a normal vector of the plane extends through the first position.

Clause 4. The reverberation chamber according to any of the clauses 1-3, wherein the structure is configured to substantially prevent a direct reflection of electromagnetic waves via the structure back to the first position.

Clause 5. The reverberation chamber according to any of the clauses 1-4, wherein the structure is configured to reduce a total energy directly reflected back to the first position via the structure by at least 90% with respect to what would be reflected back by a substantially flat surface extending in the plane in which said first wall extends and having a same reflectance parameter as the structure, preferably at least 95%, more preferably at least 99%.

Clause 6. The reverberation chamber according to any of the clauses 1-5, wherein the structure extends towards the first position with respect to the plane in which the first wall extends.

Clause 7. The reverberation chamber according to any of the clauses 1-6, wherein the structure is arranged such that, for substantially any angle of propagation of electromagnetic waves within an angular range of at least 45 degrees with respect to a central axis extending from the first position, a direct reflection of electromagnetic waves back to the first position is substantially prevented.

Clause 8. The reverberation chamber according to any of the clauses 1-7, wherein the structure comprises one or more convex shapes.

Clause 9. The reverberation chamber according to clause 8, wherein the convex shape(s) are pyramidal, each including a plurality of oblique side surfaces with respect to the plane in which the first wall extends, wherein, preferably, an angle of the side surfaces with respect to the plane in which the first wall extends lies in a range between 10-80 degrees, preferably between 20-60 degrees, such as 25 degrees.

Clause 10. The reverberation chamber according to any of the clauses 1-9, wherein the structure comprises one or more concave shapes.

Clause 11. The reverberation chamber according to clause 10, wherein the concave shapes include one or more curved surfaces oblique with respect to the plane in which the first wall extends.

Clause 12. The reverberation chamber according to any of the clauses 1-11, wherein the structure comprises a metamaterial configured to reflect electromagnetic waves, originating from the first position and incident on the structure, away from the first position.

Clause 13. The reverberation chamber according to clause 12, wherein the structure is arranged to extend parallel to the plane in which the first wall extends, and wherein the metamaterial is configured such that, for electromagnetic waves perpendicularly incident on the metamaterial, an angle of reflection is different from an angle of incidence.

Clause 14. The reverberation chamber according to any of the clauses 1-13, wherein the structure is arranged with respect to the first position and with respect to the plurality of walls such that the structure is further configured to substantially prevent one or more indirect reflections of electromagnetic waves originating from the first position back to the first position via the structure and one or more of the plurality of walls.

Clause 15. The reverberation chamber according to any of the clauses 1-14, wherein the first position corresponds to a position from which electromagnetic waves are effectively radiated by the transmitting antenna at least during operation.

Clause 16. The reverberation chamber according to any of the clauses 1-15, wherein the chamber volume comprises a plurality of said first positions together defining a first positioning space where the transmitting antenna can be received, wherein the structure is arranged along a shortest path from each first position to a plane in which said first wall extends and is configured to reflect at least part of electromagnetic waves originating from respective first positions and incident on the structure, away from said respective first positions.

Clause 17. The reverberation chamber according to clause 16, wherein the structure is further configured to reflect at least part of electromagnetic waves originating from the first positioning space and incident on the structure away from said first positioning space.

Clause 18. The reverberation chamber according to any of the clauses 1-17, wherein the chamber volume is further configured to receive, at a second position, a receiving antenna configured to receive electromagnetic waves.

Clause 19. The reverberation chamber according to clause 18, wherein the reverberation chamber further comprises an electromagnetically reflective shielding element arranged between the first position and the second position to prevent a line-of-sight path of electromagnetic waves between the first position and the second position.

Clause 20. The reverberation chamber according to any of the clauses 1-19, wherein the reverberation chamber further comprises one or more electromagnetically reflective mode stirring units arranged in the chamber volume and configured to be adjustable between a plurality of mode stirring states, corresponding to different positions and/or orientations of said one or more stirring units or otherwise configurable reflective states thereof, to thereby change a reflection behavior of electromagnetic waves within the chamber volume.

Clause 21. The reverberation chamber according to any of the clauses 1-20, wherein the reverberation chamber further comprises an adjustment element, such as a movable platform, configured to move the transmitting antenna, when arranged in the chamber volume, between a plurality of position stirring states, corresponding to different positions and/or orientations of the transmitting antenna, to thereby sample the field at different locations within the chamber volume. Clause 22. The reverberation chamber according to any of the clauses 1-21, wherein the reverberation chamber comprises a plurality of said structures arranged on or integrally formed with respective walls among the plurality of walls.

Clause 23. The reverberation chamber according to clause 22, wherein the plurality of structures form an integral structure.

Clause 24. The reverberation chamber according to any of the clauses 1-23, wherein the plurality of walls are substantially orthogonal.

Clause 25. The reverberation chamber according to any of the clauses 1-24, wherein the reverberation chamber is configured to be used at an operating frequency in a range between in a range between 0.2-1000 GHz, preferably 30-300 GHz.

Clause 26. The reverberation chamber according to clause 25, wherein the structure is spaced apart from the first position by at least 1 wavelength at said operating frequency, preferably at least 30 wavelengths, more preferably at least 50 wavelengths.

Clause 27. The reverberation chamber according to any of the clauses 1-26, wherein the first position is further removed from the first wall than from a second wall among the plurality of walls opposite to the first wall.

Clause 28. The reverberation chamber according to any of the clauses 1-27, wherein the plurality of walls and the structure are made of, or coated by, a conductive metal or metal alloy, preferably one of copper, aluminum, aluminum chromate, stainless steel, and gold.

Clause 29. The reverberation chamber according to any of the clauses 1-28, wherein at least one of the plurality of walls is provided with an opening allowing access to the chamber volume, wherein the reverberation chamber further comprises a closing element configured to be movable between an open position in which the opening is exposed and a closed position in which the opening is obstructed by the closing element, wherein the closing element comprises an electromagnetically reflective inner surface facing the chamber volume when the closing element is in the closed position.

Clause 30. The reverberation chamber according to any of the clauses 1-29, wherein the reverberation chamber further comprises: a contact arranged in the chamber volume and configured to be electrically connected to the transmitting antenna at least during operation; and a connecting element electrically connected to the contact and extending to an exterior of the chamber volume for enabling external electrical access to the contact, wherein the first position is at or near a position of the contact in the chamber volume.

Clause 31. A measurement system, comprising: the reverberation chamber according to any of the clauses 1-30 in so far as depending on clause 19; a transmitting antenna arranged at the first position; a receiving antenna arranged in the chamber volume; and a control unit configured to perform a measurement of at least one characteristic of the transmitting antenna or the receiving antenna using a signal received from the receiving antenna based on electromagnetic waves received by the receiving antenna.

Clause 32. The measurement system according to clause 31, wherein the control unit is configured to perform the measurement by performing a plurality of sub-measurements and combining a result thereof, wherein during each sub-measurement the one or more mode stirring units are in different respective mode stirring states among the plurality of mode stirring states.

Clause 33. The measurement system according to clause 31 or 32, wherein the transmitting antenna is a phased-array antenna configured to emit and steer a main beam of electromagnetic waves in one of a plurality of possible directions based on a control signal, wherein the control unit is configured to perform a plurality of said measurements, wherein for each measurement the control unit controls the transmitting antenna using the control signal to steer the main beam a different respective direction.

Clause 34. The measurement system according to any of the clauses 30-33, wherein the measurement system further comprises a power detector, spectrum analyzer and/or a vector network analyzer, ‘VNA’, electrically connected to the receiving antenna for performing the measurement.

Clause 35. The measurement system according to any of the clauses 30-34, wherein the at least one characteristic comprises at least one of a total radiated power of the transmitting antenna, a radiation pattern of the transmitting antenna and/or the receiving antenna, and a noise figure of the receiving antenna.

In the above description, the present disclosure has been explained using detailed embodiments thereof. However, the present disclosure is not limited to these embodiments, and various modifications can be implemented without deviating from the scope of the present disclosure as defined by the appended claims and their equivalents.

1-34. (canceled)

35. A reverberation chamber for testing an antenna, comprising:
a plurality of electromagnetically reflective walls together defining a chamber volume, the chamber volume being configured to receive, at a first position, a transmitting antenna; and
an electromagnetically reflective structure arranged at or integrally formed with a first wall among the plurality of walls,
wherein the structure is arranged along a shortest path from the first position to a plane in which said first wall extends and is configured to substantially prevent a direct reflection of electromagnetic waves, originating from the first position and incident on the structure, back to the first position.

36. The reverberation chamber according to claim 35, wherein:
in so far as the structure is arranged at the first wall, the first wall is a substantially planar surface and the structure extends between said planar surface and the first position; or
in so far as the structure is integrally formed with the first wall, the first wall is shaped or formed to thereby integrally form the structure with the first wall, the structure extending towards or away from the first position.

37. The reverberation chamber according to claim 35, wherein the structure is positioned at a position where the plane in which the first wall extends is orthogonal to a path from the first position to said plane, or
wherein the structure is positioned at a position where a normal vector of the plane extends through the first position.

38. The reverberation chamber according to claim 35, wherein the structure is configured to reduce a total energy directly reflected back to the first position via the structure by at least 90% with respect to what would be reflected back by a substantially flat surface extending in the plane in which said first wall extends and having a same reflectance parameter as the structure, preferably at least 95%, more preferably at least 99%.

39. The reverberation chamber according to claim 35, wherein the structure extends towards the first position with respect to the plane in which the first wall extends.

40. The reverberation chamber according to claim 35, wherein the structure is arranged such that, for substantially any angle of propagation of electromagnetic waves within an angular range of at least 45 degrees with respect to a central axis extending from the first position, a direct reflection of electromagnetic waves back to the first position is substantially prevented.

41. The reverberation chamber according to claim 35, wherein at least one of the following applies:
the structure comprises one or more convex shapes, wherein, preferably, the one or more convex shapes are pyramidal, each including a plurality of oblique side surfaces with respect to the plane in which the first wall extends, wherein, more preferably, an angle of the side surfaces with respect to the plane in which the first wall extends lies in a range between 10-80 degrees, preferably between 20-60 degrees, such as 25 degrees;
the structure comprises one or more concave shapes, wherein, preferably the concave shapes include one or more curved surfaces oblique with respect to the plane in which the first wall extends;
the structure comprises a metamaterial configured to reflect electromagnetic waves, originating from the first position and incident on the structure, away from the first position, wherein, preferably, the structure is arranged to extend parallel to the plane in which the first wall extends, and the metamaterial is configured such that, for electromagnetic waves perpendicularly incident on the metamaterial, an angle of reflection is different from an angle of incidence.

42. The reverberation chamber according to claim 35, wherein the structure is arranged with respect to the first position and with respect to the plurality of walls such that the structure is further configured to substantially prevent one or more indirect reflections of electromagnetic waves originating from the first position back to the first position via the structure and one or more of the plurality of walls.

43. The reverberation chamber according to claim 35, wherein the first position corresponds to a position from which electromagnetic waves are effectively radiated by the transmitting antenna at least during operation.

44. The reverberation chamber according to claim 35, wherein the chamber volume comprises a plurality of said first positions together defining a first positioning space where the transmitting antenna can be received,
wherein the structure is arranged along a shortest path from each first position to a plane in which said first wall extends and is configured to reflect at least part of electromagnetic waves originating from respective first positions and incident on the structure, away from said respective first positions.

45. The reverberation chamber according to claim 44, wherein the structure is further configured to reflect at least part of electromagnetic waves originating from the first positioning space and incident on the structure away from said first positioning space.

46. The reverberation chamber according to claim 35, wherein the chamber volume is further configured to receive, at a second position, a receiving antenna configured to receive electromagnetic waves.

47. The reverberation chamber according to claim 46, wherein the reverberation chamber further comprises an electromagnetically reflective shielding element arranged between the first position and the second position to prevent a line-of-sight path of electromagnetic waves between the first position and the second position.

48. The reverberation chamber according to claim 35, wherein the reverberation chamber further comprises one or more electromagnetically reflective mode stirring units arranged in the chamber volume and configured to be adjustable between a plurality of mode stirring states, corresponding to different positions and/or orientations of said one or more stirring units or otherwise configurable reflective states thereof, to thereby change a reflection behavior of electromagnetic waves within the chamber volume.

49. The reverberation chamber according to claim 35, wherein the reverberation chamber further comprises an adjustment element, such as a movable platform, configured to move the transmitting antenna, when arranged in the chamber volume, between a plurality of position stirring states, corresponding to different positions and/or orientations of the transmitting antenna, to thereby sample the field at different locations within the chamber volume.

50. The reverberation chamber according to claim 35, wherein the reverberation chamber comprises a plurality of said structures arranged on or integrally formed with respective walls among the plurality of walls.

51. The reverberation chamber according to claim 50, wherein the plurality of structures form an integral structure.

52. The reverberation chamber according to claim 35, wherein at least one of the following applies:
the plurality of walls are substantially orthogonal;
the reverberation chamber is configured to be used at an operating frequency in a range between in a range between 0.2-1000 GHz, preferably 30-300 GHz, wherein, preferably, the structure is spaced apart from the first position by at least 1 wavelength at said operating frequency, more preferably at least 30 wavelengths, even more preferably at least 50 wavelengths;
the first position is further removed from the first wall than from a second wall among the plurality of walls opposite to the first wall;
the plurality of walls and the structure are made of, or coated by, a conductive metal or metal alloy, preferably one of copper, aluminum, aluminum chromate, stainless steel, and gold;
at least one of the plurality of walls is provided with an opening allowing access to the chamber volume, wherein the reverberation chamber further comprises a closing element configured to be movable between an open position in which the opening is exposed and a closed position in which the opening is obstructed by the closing element, wherein the closing element comprises an electromagnetically reflective inner surface facing the chamber volume when the closing element is in the closed position; and
the reverberation chamber further comprises a contact arranged in the chamber volume and configured to be electrically connected to the transmitting antenna at least during operation, and
a connecting element electrically connected to the contact and extending to an exterior of the chamber volume for enabling external electrical access to the contact, wherein the first position is at or near a position of the contact in the chamber volume.

53. A measurement system, comprising:
the reverberation chamber according to claim 35, wherein the reverberation chamber further comprises an adjustment element, such as a movable platform, configured to move the transmitting antenna, when arranged in the chamber volume, between a plurality of position stirring states, corresponding to different positions and/or orientations of the transmitting antenna, to thereby sample the field at different locations within the chamber volume;
a transmitting antenna configured to be arranged at the first position;
a receiving antenna configured to be arranged in the chamber volume; and
a control unit configured to perform a measurement of at least one characteristic of the transmitting antenna or the receiving antenna using a signal received from the receiving antenna based on electromagnetic waves received by the receiving antenna.

54. The measurement system according to claim 53, wherein at least one of the following applies:
the control unit is configured to perform the measurement by performing a plurality of sub-measurements and combining a result thereof, wherein during each sub-measurement the one or more mode stirring units are in different respective mode stirring states among the plurality of mode stirring states;
the transmitting antenna is a phased-array antenna configured to emit and steer a main beam of electromagnetic waves in one of a plurality of possible directions based on a control signal, wherein the control unit is configured to perform a plurality of said measurements, wherein for each measurement the control unit controls the transmitting antenna using the control signal to steer the main beam a different respective direction;
the measurement system further comprises a power detector, spectrum analyzer and/or a vector network analyzer, ‘VNA’, electrically connected to the receiving antenna for performing the measurement; and
the at least one characteristic comprises at least one of a total radiated power of the transmitting antenna, a radiation pattern of the transmitting antenna and/or the receiving antenna, and a noise figure of the receiving antenna.
